(19) United States
(12) Patent Application Publication
(10) Pub. No.: US 2007/0188270 A1
(43) Pub. Date: Aug. 16, 2007

(54) FILM BULK ACOUSTIC RESONATOR AND FILM BULK ACOUSTIC RESONATOR FILTER

(75) Inventors: Ryoichi Ohara, Kanagawa-ken (JP); Naoko Yanase, Kanagawa-ken (JP); Kenya Sano, Kanagawa-ken (JP); Takaaki Yasumoto, Kanagawa-ken (JP); Kazuhiko Itaya, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/671,206

(22) Filed: Feb. 5, 2007

(30) Foreign Application Priority Data
Feb. 14, 2006 (JP) 2006-036029

(51) Int. Cl. H03H 9/58

(52) U.S. Cl. 333/189

(57) ABSTRACT

A film bulk acoustic resonator includes: a support substrate; and a laminated body provided on the support substrate, a portion of the laminated body being supported by the support substrate and another portion of the laminated body being spaced from the support substrate. The laminated body includes: a first electrode primarily composed of aluminum; a piezoelectric film laminated on the first electrode and primarily composed of aluminum nitride; and a second electrode laminated on the piezoelectric film. The second electrode is primarily composed of a metal having a density of 1.9 or more times the density of aluminum.

### CROSS-REFERENCE TO RELATED APPLICATIONS

This application is based upon and claims the benefit of priority from the prior Japanese Patent Application No. 2006-036029, filed on Feb. 14, 2006; the entire contents of which are incorporated herein by reference

### BACKGROUND OF THE INVENTION

1. Field of the Invention

This invention relates to a film bulk acoustic resonator and a film bulk acoustic resonator filter, and more particularly to a film bulk acoustic resonator and a film bulk acoustic resonator filter based on aluminum nitride.

2. Background Art

With the development of wireless communication technology and its transition to new systems, there is a growing demand for communication devices adaptable to a plurality of transmission/reception systems. In addition, with the enhancement of performance and functionality of mobile wireless terminals, the number of parts installed tends to increase significantly. In particular, a signal branching filter occupies a large proportion in footprint, and its downsizing is strongly required.

This filter can be downsized through the use of a thin film bulk acoustic resonator (FBAR). Hence it is expected that this filter is installed in RF antenna filters for gigahertz-band W-CDMA and duplexers for mobile information terminals. As a piezoelectric, which is the main part of the FBAR, aluminum nitride (AlN) can be grown on an aluminum (Al) electrode to obtain a highly-oriented AlN film, for example. However, Al induces spurious vibration due to its small acoustic impedance, and unfortunately, interference with unwanted noise is likely to occur (2004 IEEE Ultrasonics Symposium Vol. 1, pp. 429-32). In this respect, molybdenum (Mo), for example, may be used in the electrode as a metal having a higher density and acoustic impedance than Al. However, while the spurious vibration can be suppressed, the orientation of the AlN film is deteriorated, and desired filter characteristics may not be achieved (JP 2004-064785A).

### SUMMARY OF THE INVENTION

According to an aspect of the invention, there is provided a film bulk acoustic resonator including: a support substrate; and a laminated body provided on the support substrate, a portion of the laminated body being supported by the support substrate and another portion of the laminated body being spaced from the support substrate, the laminated body including: a first electrode primarily composed of aluminum; a piezoelectric film laminated on the first electrode and primarily composed of aluminum nitride; and a second electrode laminated on the piezoelectric film and primarily composed of a metal having a density of 1.9 or more times the density of aluminum.

According to another aspect of the invention, there is provided a film bulk acoustic resonator including: a first electrode primarily composed of aluminum; a piezoelectric film laminated on the first electrode; and a second electrode laminated on the piezoelectric film and primarily composed of a metal having a density of 1.9 or more times the density of aluminum.

According to another aspect of the invention, there is provided a film bulk acoustic resonator filter comprising the film bulk acoustic resonator having: a support substrate; and a laminated body provided on the support substrate, a portion of the laminated body being supported by the support substrate and another portion of the laminated body being spaced from the support substrate, the laminated body including: a first electrode primarily composed of aluminum; a piezoelectric film laminated on the first electrode and primarily composed of aluminum nitride; and a second electrode laminated on the piezoelectric film and primarily composed of a metal having a density of 1.9 or more times the density of aluminum.

### BRIEF DESCRIPTION OF THE DRAWINGS

FIGS. 1A and 1B illustrate an example FBAR according to an embodiment of the invention, where FIG. 1A is a schematic plan view and FIG. 1B is an enlarged cross-sectional view taken along line A-A.

FIG. 2A is a plan view of FIG. 1A, and FIG. 2B is a bottom view of FIG. 1A.

FIGS. 3A and 3B show an FBAR of a comparative example, where FIG. 3A is a schematic plan view and FIG. 3B is an enlarged cross-sectional view taken along line A-A.

FIG. 4 is a graph illustrating the relationship between frequency and impedance of the FBAR of FIG. 1 according to the embodiment.

FIG. 5 is a graph illustrating the relationship between frequency and impedance of the comparative FBAR of FIG. 3.

FIG. 6 is a graph showing a simulation result for the relationship between the distance in the lamination direction from the first (Al) electrode 40 and the strain energy for the FBAR of the present example shown in FIG. 1.

FIG. 7 is a graph showing a simulation result for the relationship between the distance in the lamination direction from the first (Al) electrode 40 and the strain energy for the FBAR of the comparative example shown in FIG. 3.

FIG. 8 is a Smith chart showing the impedance of the FBAR of the present example shown in FIG. 1.

FIG. 9 is a Smith chart showing the impedance of the FBAR of the comparative example shown in FIG. 3.

FIG. 10 is a graph showing the relationship between the material density used in the second electrode 60 and the strain energy fraction of the first electrode 40.

FIG. 11 is a graph showing a simulation result for the relationship between the distance in the lamination direction from the first (Al) electrode 40 and the strain energy in the second electrode 60 material for the FBAR according to the embodiment.

FIGS. 12A to 12C are process cross-sectional views illustrating a method of manufacturing an FBAR according to the embodiment.

FIGS. 13A and 13B illustrate a second example of the FBAR according to the embodiment of the invention, where FIG. 13A is a cross-sectional view and FIG. 13B is an enlarged cross-sectional view taken along line A-A.

FIG. 14 is a graph showing the relationship between the film thickness of the second (Al) electrode normalized by the thickness of the first (Al) electrode 40 and the total strain energy fraction of the first and second electrode 60.

FIG. 15 is a schematic cross-sectional view illustrating a third example of the FBAR according to the embodiment of the invention.

FIG. 16 is a schematic cross-sectional view illustrating an FBAR filter 15 based on the FBARs according to the embodiment.

FIG. 17 is an exploded plan view of the FBAR filter 15.

FIG. 18 illustrates a schematic circuit diagram of the FBAR filter 15.

FIG. 19 is a graph showing the relationship between frequency and impedance.

FIG. 20 is a circuit diagram illustrating the internal circuit configuration of a voltage controlled oscillator 165 equipped with FBARs according to the embodiment.

FIG. 21 is a schematic view of a mobile phone equipped with an FBAR according to the embodiment.

FIG. 22 is a schematic view of a PDA equipped with an FBAR according to the embodiment.

FIG. 23 is a schematic view of a notebook personal computer equipped with an FBAR according to the embodiment.

### DETAILED DESCRIPTION OF THE INVENTION

An embodiment of the invention will now be described with reference to the drawings.

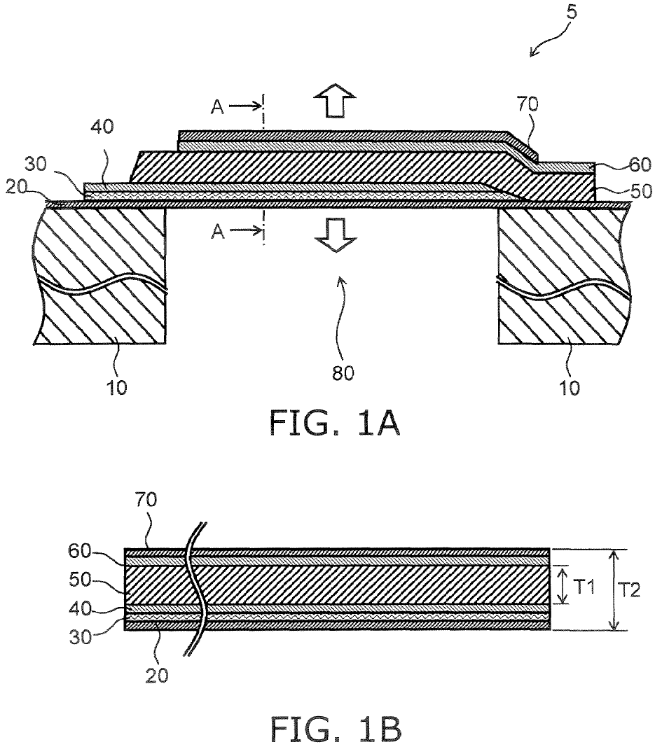

FIGS. 1A and 1B illustrate an example FBAR according to an embodiment of the invention, where FIG. 1A is a schematic plan view thereof and FIG. 1B is an enlarged cross-sectional view taken along line A-A in FIG. 1A.

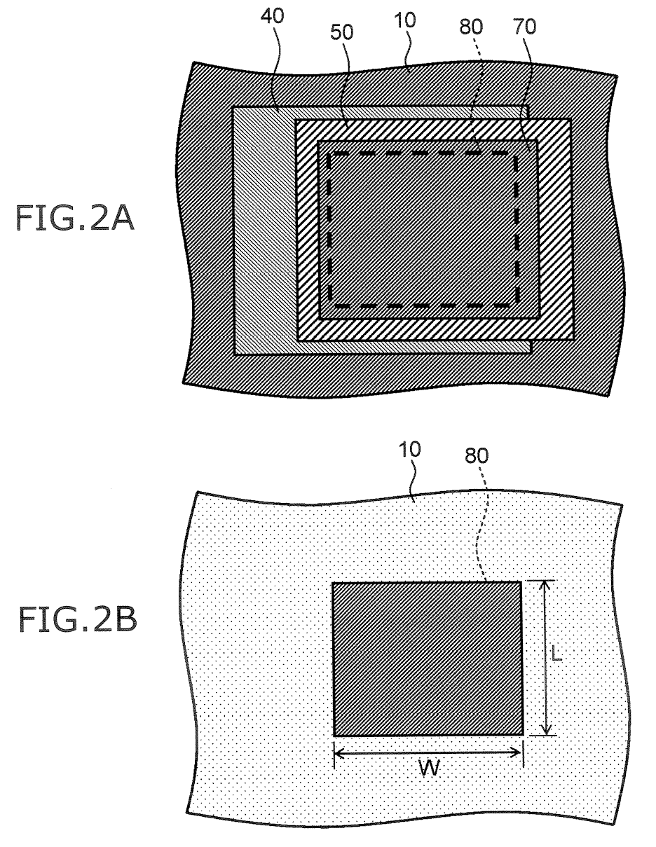

FIG. 2A is a plan view of FIG. 1A, and FIG. 2B is a bottom view of FIG. 1A.

An FBAR 5 of the embodiment has a first passivation layer 20 of e.g. silicon nitride (SiNx) entirely on a major surface of a support substrate 10 having a cavity 80. The FBAR 5 is illustratively configured so that, on the first passivation layer 20, a foundation layer 30 primarily composed of amorphous metal such as tantalum aluminum alloy (TaAl), a first electrode 40 primarily composed of Al, an AlN film having piezoelectric characteristics, a second electrode 60 of e.g. molybdenum (Mo), and a second passivation layer 70 of e.g. SiN are laminated in this order.

The cavity 80 formed in the support substrate 10 is penetrated parallel to the vibration direction of the AlN film 50 so that the AlN film 50 is not in contact with the support substrate 10 when the AlN film 50 is vibrated in the thickness direction. As described later in detail, the cavity 80 does not necessarily need to penetrate the support substrate 10, but needs only to be formed so as not to prevent the vibration of the AlN film 50. For example, the cavity 80 can be formed by forming a resonator on a sacrificial layer and finally etching away the sacrificial layer. While the cavity 80 is closed with the first passivation layer 20, the cavity 80 may be closed with the second passivation layer 70 by reversing the film lamination upside down. In the embodiment, for the sake of convenience, the passivation layer and electrode closer to the support substrate 10 are referred to as the first passivation layer 20 and the first electrode 40, whereas those being more distant are referred to as the second passivation layer 70 and the second electrode 60.

The first and second passivation layer 20, 70 prevent the characteristics variation such as the variation of resonance frequency or the decrease of Q-value (Quality factor) due to oxidation of the Mo electrode 60 and the TaAl layer 30 by the atmosphere gas and moisture. The foundation layer 30 primarily composed of amorphous metal such as TaAl serves as a foundation layer for obtaining a highly-oriented Al electrode 40 as described later. The first electrode 40 primarily composed of Al decreases the electric resistance of the resonator, and also serves as a foundation layer for forming a highly-oriented AlN film 50.

The passband of the FBAR 5 can be tuned by adjusting the film thickness of the AlN film 50 or the dimensions of the cavity 80. For a passband frequency of 2 gigahertz, for example, the film thickness T1 of the AlN film is 1.5 to 2.0 micrometers, and the film thickness T2 between the passivations 20 and 70 is 2.0 to 2.5 micrometers. For an input/output impedance of 50 ohms, for example, the cavity 80 can be configured as a square or rectangle having a length L and a width W of 100 to 200 micrometers, respectively.

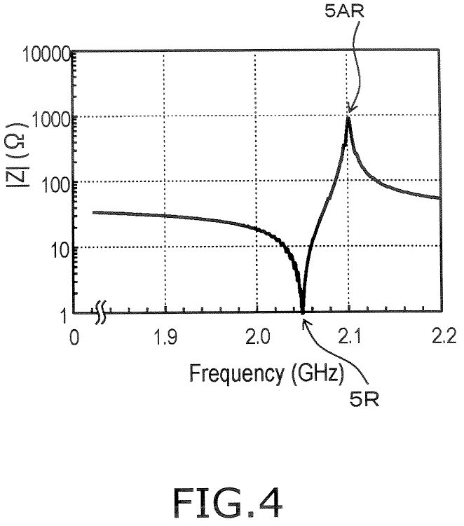

In the FBAR 5, when the first electrode 40 and the second electrode 60 sandwiching the AlN film 50 are energized, the AlN film 50 elastically vibrates in the vertical direction and hence exhibits frequency characteristics as shown in FIG. 4, described later. A band-pass filter can be realized by connecting a plurality of resonators of this type having different resonance frequencies.

According to the embodiment, by selecting the density of the second electrode 60 to be higher than the density of Al used in the first electrode, spurious vibration can be suppressed.

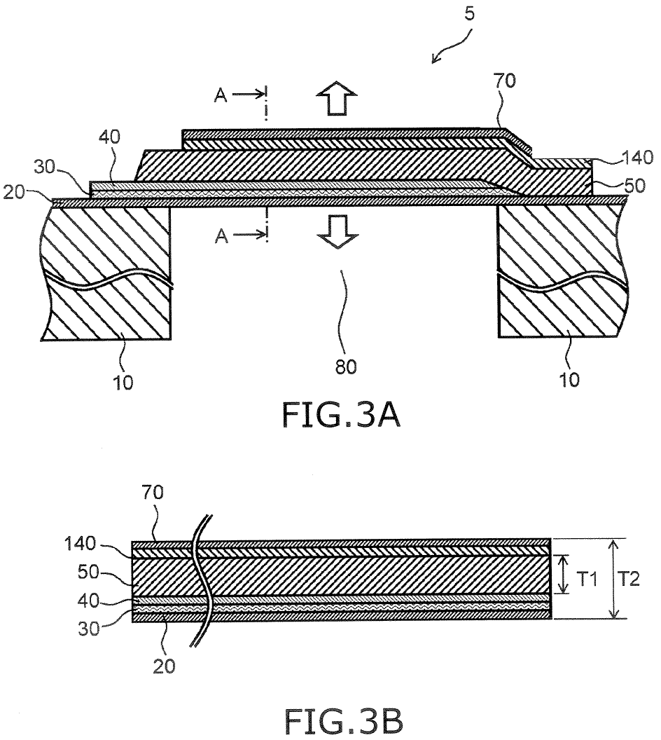

FIGS. 3A and 3B show an FBAR 5 of a comparative example, where FIG. 3A is a schematic plan view and FIG. 3B is an enlarged cross-sectional view taken along line A-A.

With regard to these figures, elements similar to those described above with reference to FIGS. 1 and 2 are marked with the same reference numerals and not described in detail.

This comparative example is based on an Al electrode 140 instead of the second electrode 60 made of Mo in the present example shown in FIG. 1. That is, the comparative example is configured so that the AlN film 50 is sandwiched between the Al electrodes 40 and 140.

FIG. 4 is a graph illustrating the relationship between frequency and impedance of the FBAR 5 of FIG. 1 according to the embodiment.

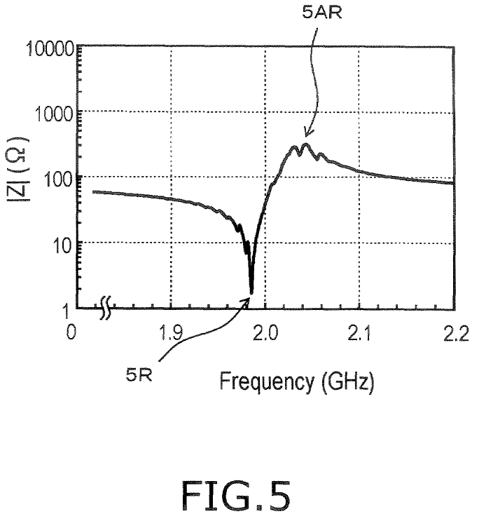

FIG. 5 is a graph illustrating the relationship between frequency and impedance of the FBAR 5 of FIG. 3 in the comparative example.

In these graphs, the horizontal axis represents frequency (in gigahertz), and the vertical axis represents the absolute value of impedance (in ohms). These impedance characteristics were measured using a vector network analyzer.

First, the comparative example shown in FIG. 5 is described.

When an Al electrode 140 is used for the second electrode 60, as can be seen in FIG. 5, the resonance frequency 5R exhibits a resonance characteristic having a single sharp peak, whereas the antiresonance frequency 5AR is split into a plurality of peaks due to spurious vibration.

In contrast, according to the embodiment, as can be seen in FIG. 4, both the resonance frequency 5R and the antiresonance frequency 5AR exhibit a resonance characteristic having a single sharp peak. This resonance characteristic having a single sharp peak is attributable to the suppression of spurious vibration through the use of Mo in the second electrode 60.

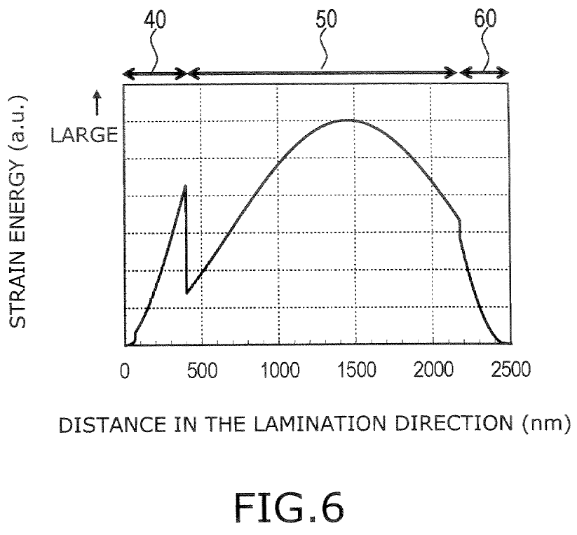

FIG. 6 is a graph showing a simulation result for the relationship between the distance in the lamination direction from the first (Al) electrode 40 and the strain energy for the FBAR 5 of the present example shown in FIG. 1.

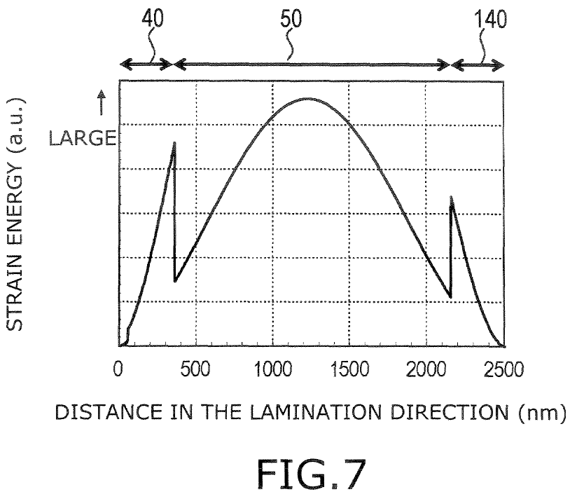

FIG. 7 is a graph showing a simulation result for the relationship between the distance in the lamination direction from the first (Al) electrode 40 and the strain energy for the FBAR 5 of the comparative example shown in FIG. 3.

In these graphs, the horizontal axis represents the distance in the lamination direction (in nanometers), and the vertical axis represents strain energy (a.u.). The distance in the lamination direction used herein refers to the distance along the lamination direction from the surface of the first (Al) electrode 40.

First, the comparative example of FIG. 7 is described.

When an Al electrode 140 is used instead of the second electrode 60, as can be seen in FIG. 7, strain energy peaks are formed in the AlN film 50, the first electrode 40, and the second electrode 140, respectively. Al is a relatively soft material, and hence tends to accumulate strain energy due to vibration. In particular, the strain energy peak in the first electrode 40 is high. The reason for this is contemplated as follows. The TaAl layer 30 provided below the first electrode 40 has a higher density than the Al electrode 40, and hence the position of the maximal strain energy is located on the first electrode 40 side. The strain energy is released in the first electrode 40 and increases spurious vibration. At this time, the strain energy produced in the first electrode 40 reaches 8.0 percent, for example, of the strain energy accumulated in the resonator.

In contrast, according to this example, as can be seen in FIG. 6, the second electrode 60 scarcely accumulates strain energy because Mo is used in the second electrode 60. The reason for this is that Mo is a relatively hard material and less susceptible to strain due to vibration. Furthermore, because the second electrode 60 is made of a high density metal, the position of the maximal vibration energy is shifted to the second electrode 60 side. As a result, the strain energy produced in the first electrode 40 is decreased, and spurious modes are suppressed. More specifically, the strain energy accumulated in the first electrode 40 is 4.7 percent of the strain energy accumulated in the entire resonator, which is lower than in the comparative example and indicates that spurious modes are suppressed.

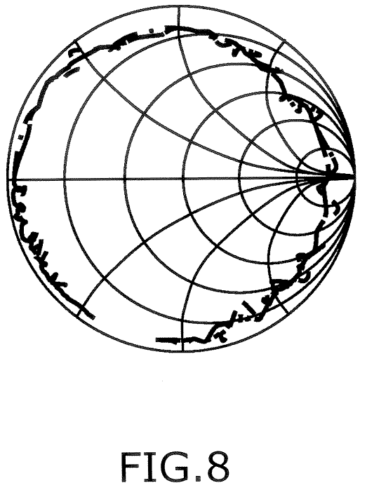

FIG. 8 is a Smith chart showing the normalized impedance of the FBAR 5 of the present example shown in FIG. 1.

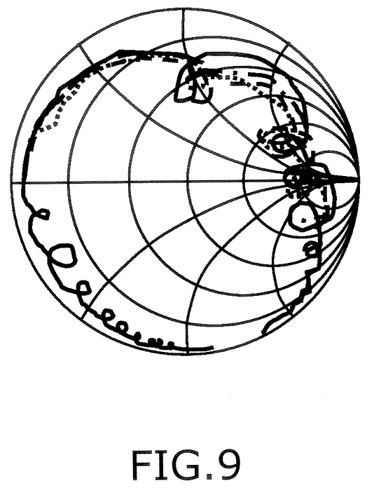

FIG. 9 is a Smith chart showing the normalized impedance of the FBAR 5 of the comparative example shown in FIG. 3.

First, the comparative example of FIG. 9 is described.

When an Al electrode 140 is used for the second electrode 60, as can be seen in FIG. 9, strong spurious vibration is observed in the vicinity of the antiresonance frequency with a low Q-value of the resonance. This is attributable to the effect of spurious vibration due to the vibration energy accumulated in Al.

In contrast, according to this example, as shown in FIG. 8, through the use of Mo in the second electrode 60, the spurious vibration in the vicinity of the antiresonance frequency is significantly suppressed, and the Q-value is also improved. It turns out that the impedance locus is enhanced. This is presumably because spurious vibration is suppressed by selecting the density of the second electrode 60 to be higher than the density of Al used in the first electrode.

Next, the material used in the second electrode 60 is described in detail.

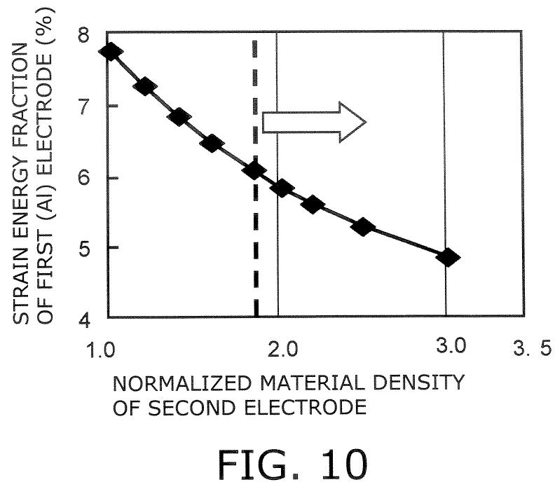

FIG. 10 is a graph showing the relationship between the material density used in the second electrode 60 and the strain energy fraction of the first electrode 40.

The horizontal axis represents the material density (in g/cm³) of the second electrode 60 normalized by the density of Al (2.7 g/cm³). The vertical axis represents the fraction (in percent) of the strain energy in the first (Al) electrode 40 to the total strain energy.

It is observed that the strain energy fraction of the first (Al) electrode 40 tends to decrease as the density of material used in the second electrode 60 increases. If the strain energy in the Al electrode 40 is 6.0 percent or less, the effect of spurious vibration is almost negligible. Therefore, it turns out that spurious vibration is suppressed when the density of material used in the second electrode 60 is 1.9 or more times the density of Al.

Besides Mo, the second electrode 60 can be made of, for example, copper (Cu), nickel (Ni), ruthenium (Ru), cobalt (Co), platinum (Pt), rhodium (Rh), tungsten (W), iridium (Ir), silver (Ag), or gold (Au). Among them, in particular, Cu, Ni, and Mo are preferable because they can be used in common with the manufacturing process for other devices.

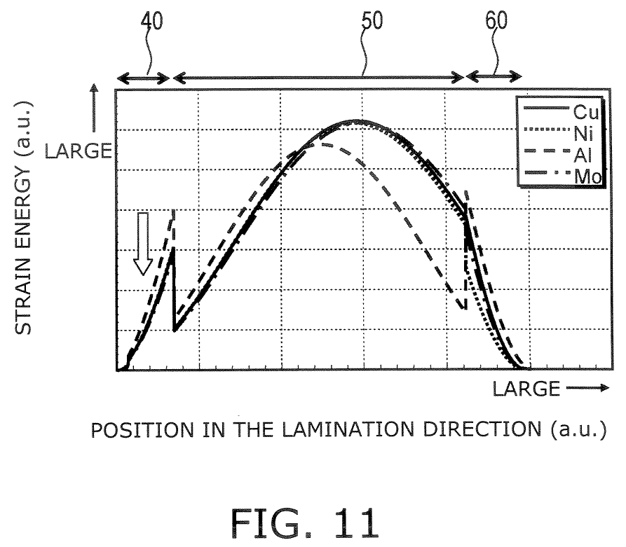

FIG. 11 is a graph showing a simulation result for the relationship between the distance in the lamination direction from the first (Al) electrode 40 and the strain energy in the second electrode 60 material for the FBAR 5 according to the embodiment.

In this graph, the horizontal axis represents the distance (a.u.) in the lamination direction from the first (Al) electrode 40, and the vertical axis represents strain energy (a.u.). In this example, nickel (Ni, 8.91 g/cm³), copper (Cu, 8.96 g/cm³), and Mo (10.22 g/cm³), having two or more times the density of Al, are used for the material of the second electrode 60, whereas Al is used as a comparative example.

Table 1 summarizes the relationship between the density of various materials used in the second electrode 60 and the strain energy fraction of the first electrode 40. Here, a significant effect of spurious modes is represented as “Yes”, and a negligible effect of spurious modes is represented as “No”.

TABLE 1

| | | | MATERIAL | | |
|---|---|---|---|---|---|
| | | | DENSITY | STRAIN | EFFECT |
| | | DENSITY | NORMALIZED | ENERGY | OF |
| | MATERIAL | g/cm³ | BY Al | FRACTION % | SPURIOUS |
| PRESENT | Mo | 10.2 | 3.8 | 4.4 | NO |
| EXAMPLE | | | | | |
| PRESENT | Ni | 8.9 | 3.3 | 4.7 | NO |
| EXAMPLE | | | | | |
| PRESENT | Cu | 8.96 | 3.7 | 4.5 | NO |
| EXAMPLE | | | | | |
| COMPARATIVE | Al | 2.7 | 1.0 | 6.6 | YES |
| EXAMPLE | | | | | |

First, the comparative example is described. When the second electrode 60 is made of Al, the strain energy fraction of the first electrode 40 is 6.6 percent, for example. This is higher than 6.0 percent, which is the threshold of being affected by spurious modes. Thus it turns out that the effect of spurious modes is present.

In contrast, when the second electrode 60 is made of Ni, Cu, or Mo, the strain energy fraction of the first (Al) electrode 40 is illustratively 4.7 percent for Ni, 4.5 percent for Cu, and 4.4 percent for Mo, which are lower than 6.0 percent. Thus it turns out that the effect of spurious modes is suppressed.

Furthermore, the second electrode 60 of the invention having a film thickness t of at least 50 nanometers to 700 nanometers (50≦t≦700) achieves desired characteristics of the FBAR 5. The film thickness less than 50 nanometers results in high electric resistance, which increases heat loss. The film thickness greater than 700 nanometers results in accumulation of strain energy inside the second electrode 60, which deteriorates piezoelectric characteristics.

The material used in the second electrode 60 has been described in detail.

Next, a method of manufacturing an FBAR 5 according to the embodiment is described.

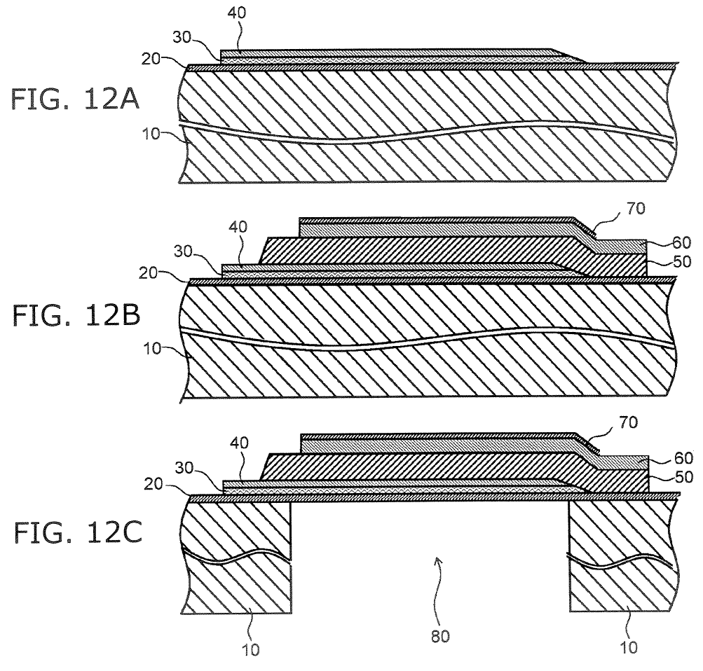

FIGS. 12A to 12C are process cross-sectional views illustrating a method of manufacturing an FBAR 5 according to the embodiment.

The FBAR 5 of the embodiment is manufactured as follows.

First, as shown in FIG. 12A, on a Si (silicon) support substrate 10 having a substrate thickness of about 600 micrometers is formed a thermal oxide film (not shown), and then a first passivation layer 20 of Si nitride film having a film thickness of about 50 nanometers is formed by CVD (Chemical Vapor Deposition). Next, an amorphous alloy foundation layer 30 of e.g. TaAl layer having a layer thickness of 10 nanometers and a first electrode 40 of Al having an electrode thickness of about 200 nanometers are successively grown by sputtering and then patterned by chlorine-based RIE to form a first electrode 40.

Subsequently, as shown in FIG. 12B, an AlN film 50 having a film thickness of 1.8 micrometers is grown also by sputtering and processed by chlorine-based RIE. Then a second electrode 60 of e.g. Mo having a film thickness of 250 nanometers is grown and patterned to form a second electrode 60, on which a second passivation layer 70 of Si nitride film having a film thickness of about 50 nanometers is formed by CVD.

Finally, as shown in FIG. 12C, part of the backside of the Si support substrate 10 is removed by dry etching such as Deep-RIE (Deep Reactive Ion Etching) or wet etching with an etchant such as potassium hydroxide (KOH) solution or tetramethylammonium hydroxide (TMAH) solution to form a cavity (opening).

In this example, Si is used for the support substrate 10. However, it is also possible to use other materials such as gallium arsenide (GaAs), indium phosphide (InP), quartz, glass, or plastics having heat resistance to about 200° C. In this example, the first passivation layer 20 is made of highly smooth SiNx film. However, if emphasis is placed on crystallinity and orientation, it is possible to use silicon oxide (SiO₂), aluminum nitride (AlN), and aluminum oxide (Al₂O₃). The amorphous alloy foundation layer 30 serves to form a highly-oriented Al electrode 40. The Al electrode 40 can be used as a foundation to obtain a c-axis oriented AlN film 50, which allows a filter to have reduced loss and broader bandwidth.

The etching gas for use in the Deep-RIE process includes, for example, a combination of sulfur hexafluoride (SF₆) gas and Freon (e.g., C₄F₈) gas. In this case, the SF₆ gas serves to etch the support substrate 10 for forming a cavity 80. The C₄F₈ gas serves to form a polymer protection film on the sidewall of the cavity 80. A desired cavity 80 can be formed by alternately supplying these gases. Thus the main part of the FBAR 5 of the embodiment is completed.

The method of manufacturing an FBAR 5 according to the embodiment has been described.

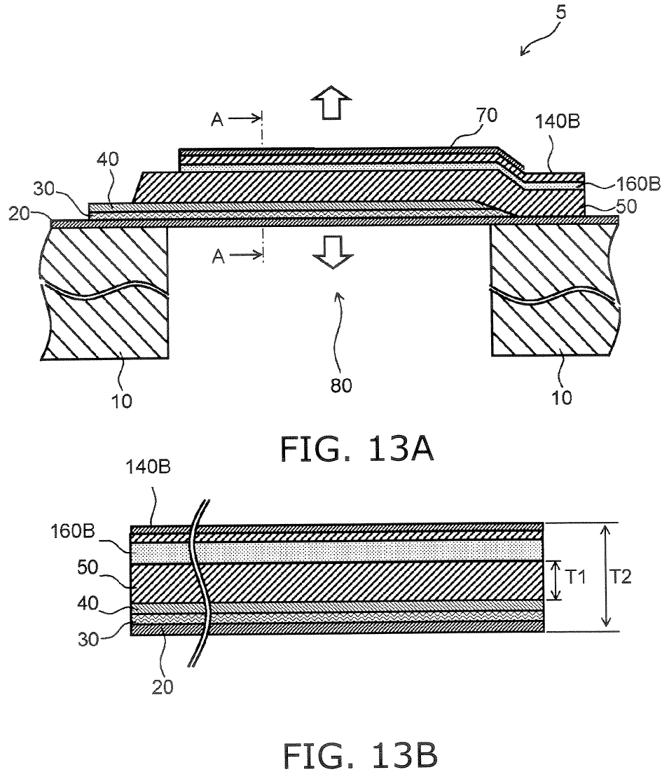

Next, reference is made to FIGS. 13 to 16 to describe other examples of the FBAR 5 according to the embodiment. With regard to these figures, elements similar to those described above with reference to FIGS. 1 to 12 are marked with the same reference numerals and not described in detail.

FIGS. 13A and 13B illustrate a second example of the FBAR 5 according to the embodiment of the invention, where FIG. 13A is a cross-sectional view thereof and FIG. 13B is an enlarged cross-sectional view taken along line A-A in FIG. 13A.

The basic structure of this example is similar to that in FIG. 1 except that an upper electrode 140B of e.g. Al is formed on the second 160B of e.g. Mo having a higher density than Al. In this structure, the upper electrode 140B of Al serves to reduce the electric resistance of the resonator. Spurious modes can be suppressed by restricting the film thickness of the upper electrode 140B of Al.

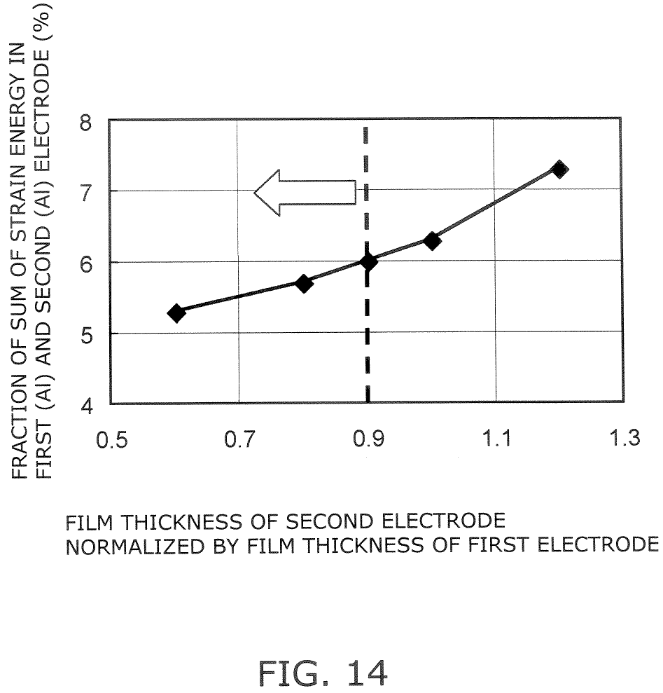

FIG. 14 is a graph showing the relationship between the film thickness of the second upper (Al) electrode 140B normalized by the film thickness of the first (Al) electrode 40 and the total strain energy fraction of the first and second upper electrode of Al. The horizontal axis represents the film thickness of the second upper (Al) electrode 140B normalized by the film thickness of the first (Al) electrode 40. The vertical axis represents the fraction (in percent) of the sum of the strain energy in the first and second upper (Al) electrode to the total strain energy accumulated in the resonator.

It can be seen that, with the decrease of the normalized film thickness of the second upper (Al) electrode 140B, the fraction of the sum of the strain energy in the first electrode 40 and second upper electrode 140B decreases. Thus, according to this example, the effective electromechanical coupling coefficient can be increased by using Mo in the electrode, and at the same time the electric resistance can be decreased by providing the Al electrode 140B thereon. Here the electric resistivity of Mo is 5.2×10⁻⁶ ohm-centimeter, whereas that of Al is as low as 2.7×10⁻⁶ ohm-centimeter.

As described above with reference to FIG. 10, spurious vibration has little effect if the strain energy in the Al electrode is 6.0 percent or less. Thus, if the film thickness of the second (Al) electrode is about 0.9 or less times that of the first electrode 40, the fraction of the sum of the strain energy in the first (Al) electrode 40 and second upper (Al) electrode 140B can be decreased to 6.0 percent or less, thereby suppressing spurious vibration.

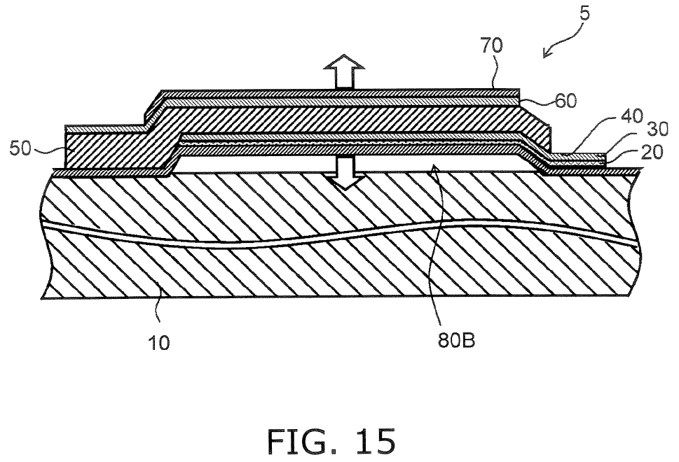

FIG. 15 is a schematic cross-sectional view illustrating a third example of the FBAR 5 according to the embodiment of the invention.

In this example, a laminated body having a spaced portion is formed on a generally planar major surface of a support substrate 10, and a hollow 80B is formed between the spaced portion of the laminated body and the support substrate 10. This structure can also realize good impedance characteristics because the vibrating FBAR 5 is not in contact with the support substrate 10. Furthermore, in this structure, an FBAR 5 having impedance characteristics similar to those in FIG. 1 is realized, and at the same time there is no need to form a cavity 80 by Deep-RIE. Thus the lead time of the manufacturing process can be reduced.

In producing this resonator, to form a desired hollow 80B, a sacrificial layer of silicate glass is first formed on the support substrate 10 by CVD. A laminated body is formed on the sacrificial layer and on part of the surface of the support substrate 10. Then the sacrificial layer is removed using an etchant such as ammonium fluoride or dilute hydrofluoric acid to form a hollow 80B.

In the FBAR 5 of this example again, as described above with reference to FIG. 10, Mo or other metals can be used in the second electrode 60 to reduce strain energy in the first electrode (Al) 40, thereby suppressing spurious modes. Furthermore, in this example again, as described above with reference to FIG. 13, the second electrode 60 can be formed from an upper electrode of Al laminated on a lower electrode of Mo to reduce electric resistance. Moreover, the thickness of the upper electrode of Al can be restricted to suppress spurious modes.

The FBAR 5 according to the embodiment has been described.

Next, a description is given of an FBAR filter 15 in which a plurality of the FBARs 5 of FIG. 1 having different resonance frequencies are connected.

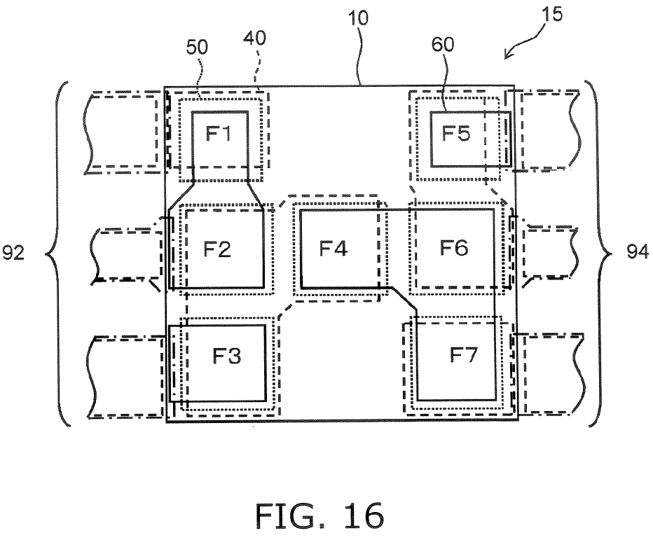

FIG. 16 is a schematic cross-sectional view illustrating an FBAR filter 15 based on the FBARs 5 according to the embodiment.

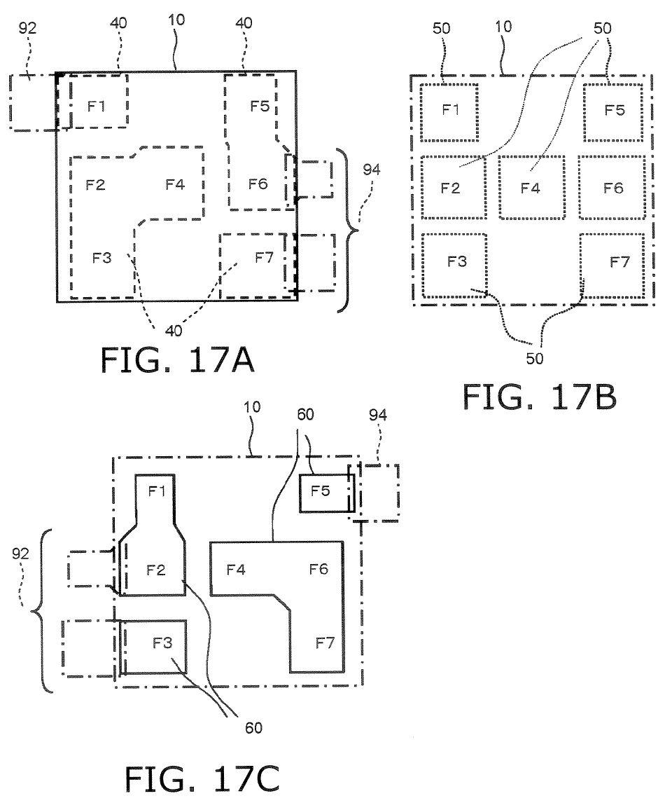

FIG. 17 is an exploded plan view thereof.

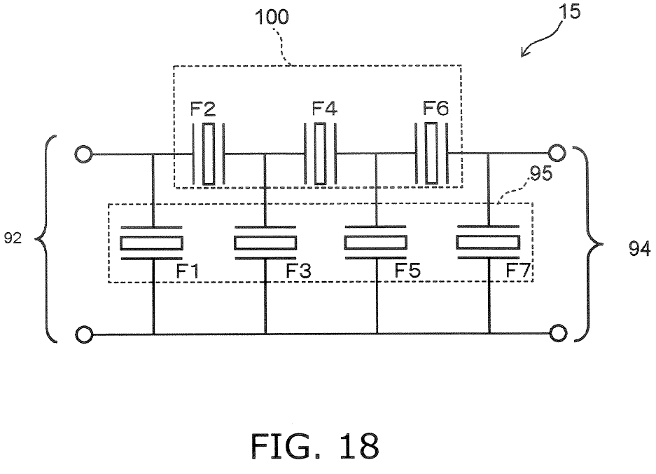

FIG. 18 illustrates a schematic circuit diagram of the FBAR filter 15 of FIG. 16.

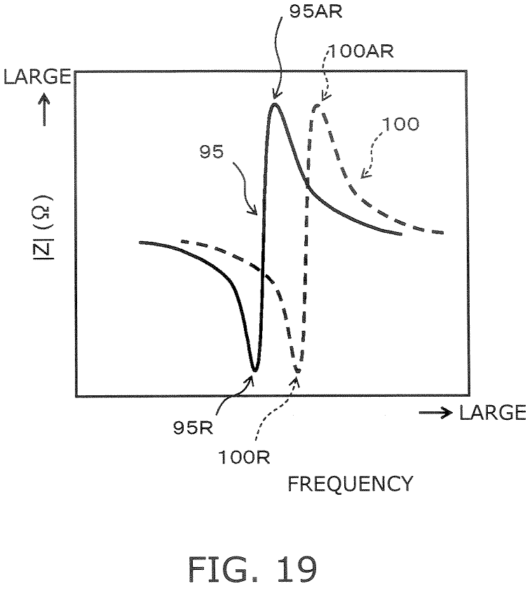

FIG. 19 is a graph showing the relationship between frequency and impedance.

As shown in FIGS. 16 to 18, the FBAR filter 15 of the embodiment is a ladder-type FBAR filter based on the FBARs 5 of FIG. 1 having different resonance frequencies in which four FBARs 5 are arranged in parallel and three FBARs 5 are arranged in series. The first electrode 40 and the second electrode 60 of each FBAR 5 are coupled to electrically connect all the FBARs 5. In the FBAR filter 15, for example, a signal is inputted to input end FBARs 5 (F1, F2, F3), passed through an FBAR 5 (F4), and outputted from output end FBARs 5 (F5, F6, F7). Here, the same effect is achieved when the input end and the output end are reversed.

Thus, as shown in FIG. 19, by a combination of parallel FBARs 95 with serial FBARs 100, a signal inputted to the input end 92 is significantly attenuated at the resonance frequency 95R of the parallel FBARs 95 and the antiresonance frequency 100AR of the serial FBARs 100, and a passband is created between the resonance frequencies. Thus only a specific frequency can be extracted from the output end 94.

An FBAR filter 15 of this type does not need fine patterning. Therefore the FBAR filter 15 can be adapted to high frequencies, and the electrodes can be made resistant to higher power. Furthermore, because the FBAR filter 15 can be formed on a semiconductor support substrate 10, it is easy to form a monolithic RF filter. Moreover, according to the embodiment, as described above with reference to FIGS. 1 to 15, FBARs 5 with suppressed spurious modes can be used to realize an FBAR filter 15 having excellent filter characteristics and high efficiency.

The embodiment of the invention has been described with reference to the examples. However, the invention is not limited to these examples. For example, the vibrating portion of the FBAR of the embodiment can be configured not only as a square, but also as a rectangle or other quadrangle, a triangle, a polygon, an irregular polygon, or any other shape, where the same effect as the embodiment is achieved.

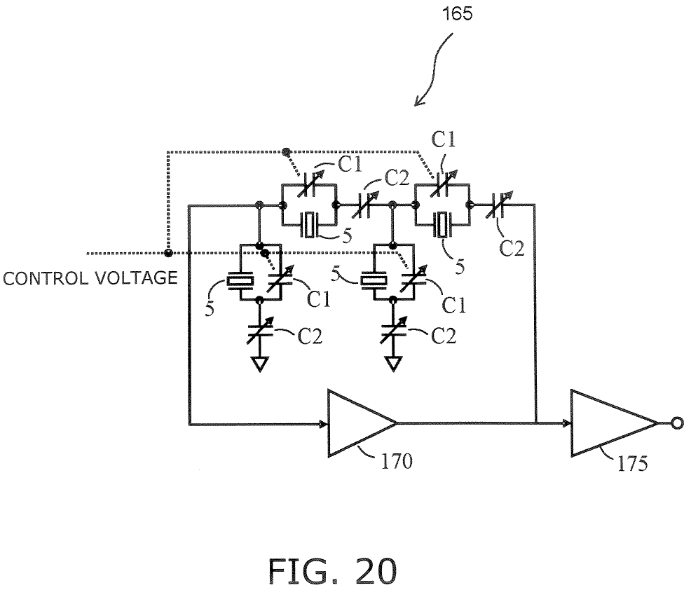

FIG. 20 is a circuit diagram illustrating the internal circuit configuration of a voltage controlled oscillator 165 equipped with FBARs according to the embodiment.

The voltage controlled oscillator (VCO) 165 has FBARs 5, an amplifier 170, a buffer amplifier 175, and variable capacitors C1, C2. Only the frequency component that has passed through the FBAR filter 15 is fed back to the input of the amplifier 170, and an output signal can be extracted, thereby achieving frequency adjustment.

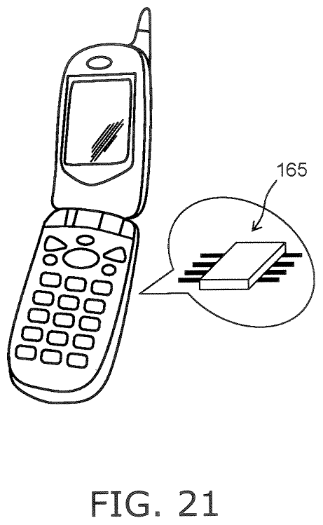

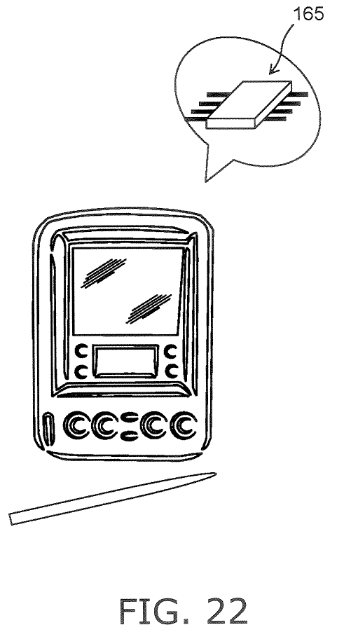

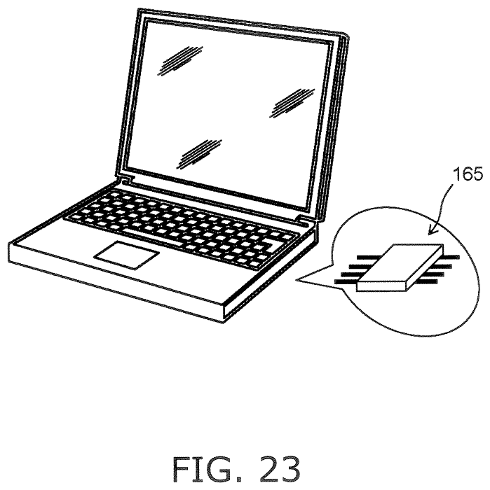

This VCO 165 can be installed on information terminal devices such as a mobile phone as shown in FIG. 21, a PDA as shown in FIG. 22, or a notebook personal computer as shown in FIG. 23, for preventing interference.

The material, composition, shape, pattern, manufacturing process and the like of any elements constituting the FBAR and the FBAR filter of this invention that are variously adapted by those skilled in the art are also encompassed within the scope of the invention as long as they include the features of the invention.

The structures of the examples can be appropriately combined with each other as long as it is technically feasible, and such combined FBAR filters are also encompassed within the scope of the invention.

1. A film bulk acoustic resonator comprising:
a support substrate; and
a laminated body provided on the support substrate, a portion of the laminated body being supported by the support substrate and another portion of the laminated body being spaced from the support substrate,
the laminated body including:
a first electrode primarily composed of aluminum;
a piezoelectric film laminated on the first electrode and primarily composed of aluminum nitride; and
a second electrode laminated on the piezoelectric film and primarily composed of a metal having a density of 1.9 or more times the density of aluminum.

2. The film bulk acoustic resonator according to claim 1, wherein the metal is any one selected from the group consisting of molybdenum (Mo), copper (Cu), nickel (Ni), ruthenium (Ru), cobalt (Co), platinum (Pt), rhodium (Rh), tungsten (W), iridium (Ir), silver (Ag), and gold (Au).

3. The film bulk acoustic resonator according to claim 1, wherein the metal is any one selected from the group consisting of molybdenum (Mo), copper (Cu), and nickel (Ni).

4. The film bulk acoustic resonator according to claim 1, wherein the laminated body further includes a third electrode laminated on the second electrode, the third electrode being primarily composed of aluminum.

5. The film bulk acoustic resonator according to claim 4, wherein the third electrode has a thickness of 0.9 or less times the thickness of the first electrode.

6. The film bulk acoustic resonator according to claim 1, wherein the laminated body further includes a foundation layer laminated under the first electrode and primarily composed of an amorphous metal.

7. The film bulk acoustic resonator according to claim 6, wherein the amorphous metal is TaAl.

8. The film bulk acoustic resonator according to claim 1, wherein a thickness of the second electrode is not less than 50 nanometers and not greater than 700 nanometers.

9. The film bulk acoustic resonator according to claim 1, wherein the piezoelectric film is oriented toward c-axis.

10. A film bulk acoustic resonator comprising:
a first electrode primarily composed of aluminum;
a piezoelectric film laminated on the first electrode; and
a second electrode laminated on the piezoelectric film and primarily composed of a metal having a density of 1.9 or more times the density of aluminum.

11. The film bulk acoustic resonator according to claim 10, wherein the piezoelectric film is primarily composed of aluminum nitride.

12. The film bulk acoustic resonator according to claim 10, wherein the metal is any one selected from the group consisting of molybdenum (Mo), copper (Cu), nickel (Ni), ruthenium (Ru), cobalt (Co), platinum (Pt), rhodium (Rh), tungsten (W), iridium (Ir), silver (Ag), and gold (Au).

13. The film bulk acoustic resonator according to claim 10, further comprising a third electrode laminated on the second electrode, the third electrode being primarily composed of aluminum.

14. The film bulk acoustic resonator according to claim 13, wherein the third electrode has a thickness of 0.9 or less times the thickness of the first electrode.

15. The film bulk acoustic resonator according to claim 10, further comprising a foundation layer laminated under the first electrode and primarily composed of an amorphous metal.

16. The film bulk acoustic resonator according to claim 15, wherein the amorphous metal is TaAl.

17. The film bulk acoustic resonator according to claim 10, wherein a thickness of the second electrode is not less than 50 nanometers and not greater than 700 nanometers.

18. The film bulk acoustic resonator according to claim 10, wherein the piezoelectric film is oriented toward c-axis.

19. A film bulk acoustic resonator filter comprising the film bulk acoustic resonator having:
a support substrate; and
a laminated body provided on the support substrate, a portion of the laminated body being supported by the support substrate and another portion of the laminated body being spaced from the support substrate,
the laminated body including:
a first electrode primarily composed of aluminum;
a piezoelectric film laminated on the first electrode and primarily composed of aluminum nitride; and
a second electrode laminated on the piezoelectric film and primarily composed of a metal having a density of 1.9 or more times the density of aluminum.

20. The film bulk acoustic resonator filter according to claim 19, wherein the metal is any one selected from the group consisting of molybdenum (Mo), copper (Cu), nickel (Ni), ruthenium (Ru), cobalt (Co), platinum (Pt), rhodium (Rh), tungsten (W), iridium (Ir), silver (Ag), and gold (Au).
